(19) United States
(12) Patent Application Publication
(10) Pub. No.: US 2025/0072088 A1
(43) Pub. Date: Feb. 27, 2025

(54) NITRIDE SEMICONDUCTOR DEVICE

(71) Applicant: ROHM CO., LTD., Kyoto-shi (JP)

(72) Inventor: Tomonori KATO, Kyoto-shi (JP)

(73) Assignee: ROHM CO., LTD., Kyoto-shi (JP)

(21) Appl. No.: 18/801,879

(22) Filed: Aug. 13, 2024

(30) Foreign Application Priority Data
Aug. 22, 2023 (JP) 2023-134779

(51) Int. Cl. H01L 29/423; H01L 29/20; H01L 29/40; H01L 29/778

(52) U.S. Cl. CPC H01L 29/42316; H01L 29/2003; H01L 29/402; H01L 29/7786

(57) ABSTRACT

A nitride semiconductor device includes an electron transit layer, an electron supply layer, a gate layer, a gate electrode on the gate layer, a source electrode, and a drain electrode. The gate layer includes a first gate portion, a second gate portion, and a recess between the first gate portion and the second gate portion. The gate electrode is arranged over both the first gate portion and the second gate portion. The nitride semiconductor device further includes an insulator located in the recess.

### CROSS-REFERENCE TO RELATED APPLICATION

This application is based upon and claims the benefit of priority from prior Japanese Patent Application No. 2023-134779, filed on Aug. 22, 2023, the entire contents of which are incorporated herein by reference.

### BACKGROUND

### 1. Field

The following description relates to a nitride semiconductor device.

### 2. Description of Related Art

High-electron-mobility transistors (HEMTs) that use nitride semiconductors, such as gallium nitride (GaN), are now being commercialized. Japanese Laid-Open Patent Publication No. 2017-073506 describes one example of a normally-off HEMT using a nitride semiconductor device.

### BRIEF DESCRIPTION OF THE DRAWINGS

FIG. 1 is a schematic plan view of an exemplary nitride semiconductor device in accordance with a first embodiment.

FIG. 2 is a schematic plan view illustrating part of the nitride semiconductor device illustrated in FIG. 1.

FIG. 3 is a schematic cross-sectional view of the nitride semiconductor device taken along line F3-F3 in FIG. 2.

FIG. 4 is a schematic, enlarged cross-sectional view illustrating part of the nitride semiconductor device illustrated in FIG. 3.

FIG. 5 is a schematic cross-sectional view of an exemplary nitride semiconductor device in accordance with a second embodiment.

FIG. 6 is a schematic cross-sectional view of an exemplary nitride semiconductor device in accordance with a third embodiment.

FIG. 7 is a schematic cross-sectional view of an exemplary nitride semiconductor device in accordance with a fourth embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a semiconductor device will now be described with reference to the accompanying drawings.

Elements in the figures are illustrated for simplicity and clarity and have not necessarily been drawn to scale. In the drawings, characteristic portions may be exaggerated and elements may not be in scale. The accompanying drawings illustrate exemplary embodiments in accordance with the present disclosure and are not intended to limit the present disclosure.

Terms such as “first”, “second”, and “third” in this disclosure are used to distinguish subjects and not used for ordinal purposes. The phrase “at least one of” as used in this disclosure means “one or more” of a desired choice. As one example, the phrase “at least one of” as used in this disclosure means “only one choice” or “both of two choices” in a case where the number of choices is two. As another example, the phrase “at least one of” as used in this disclosure means “only one single choice” or “any combination of two or more choices” if the number of its choices is three or more.

This detailed description provides a comprehensive understanding of the methods, apparatuses, and/or systems described. Exemplary embodiments may have different forms, and are not limited to the examples described.

### First Embodiment

### 1. Outline of Nitride Semiconductor Device Structure

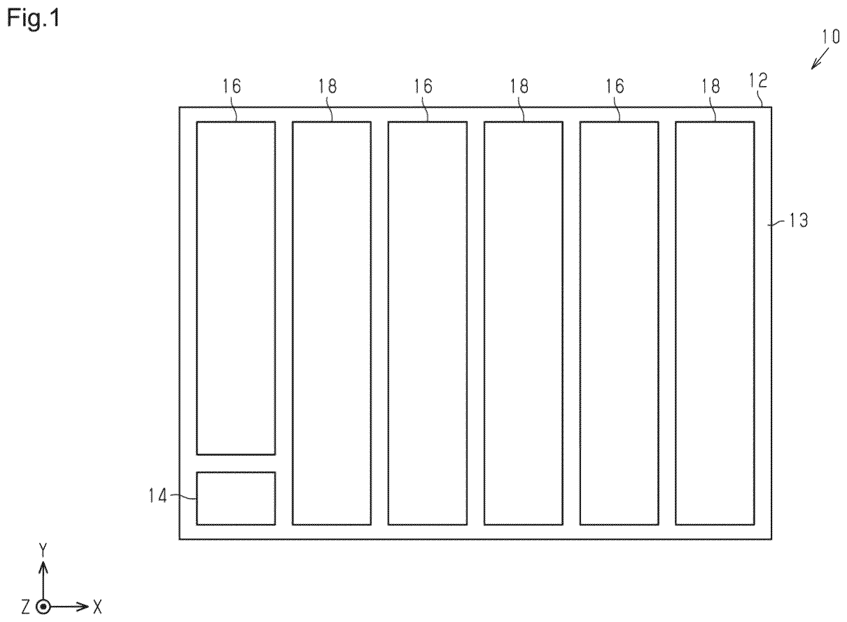

FIG. 1 is a schematic plan view of an exemplary nitride semiconductor device 10 in accordance with a first embodiment. The nitride semiconductor device 10 includes a chip main body 12. FIG. 1 and the other figures indicate X, Y, and Z axes that are orthogonal to one another. The direction of the Z-axis is orthogonal to a main surface (upper surface 13 in FIG. 1) of the chip main body 12. The term “plan view” as used in the present disclosure refers to a view of the nitride semiconductor device 10 taken from above in the Z-axis direction unless otherwise indicated.

The nitride semiconductor device 10 includes at least one gate pad 14, at least one source pad 16, and at least one drain pad 18. For example, in FIG. 1, the nitride semiconductor device 10 includes a single gate pad 14, multiple source pads 16, and multiple drain pads 18. The gate pad 14, the source pads 16, and the drain pads 18 are formed on the upper surface 13 of the chip main body 12 and may be used as external connection terminals of the nitride semiconductor device 10.

The gate pad 14, the source pads 16, and the drain pads 18 are each, for example, rectangular in plan view. The gate pad 14 may be arranged in one corner of the upper surface 13. The source pads 16 and the drain pads 18 extend in one direction in plan view (e.g., the direction of the Y-axis in FIG. 1). The source pads 16 and the drain pads 18 are alternately arranged the X-axis direction, which is orthogonal to the Y-axis direction.

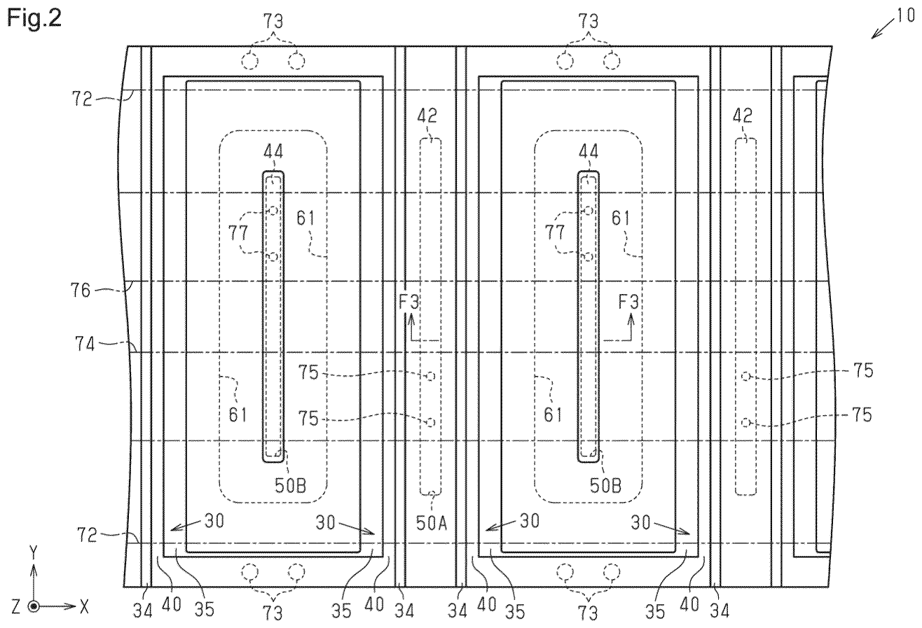

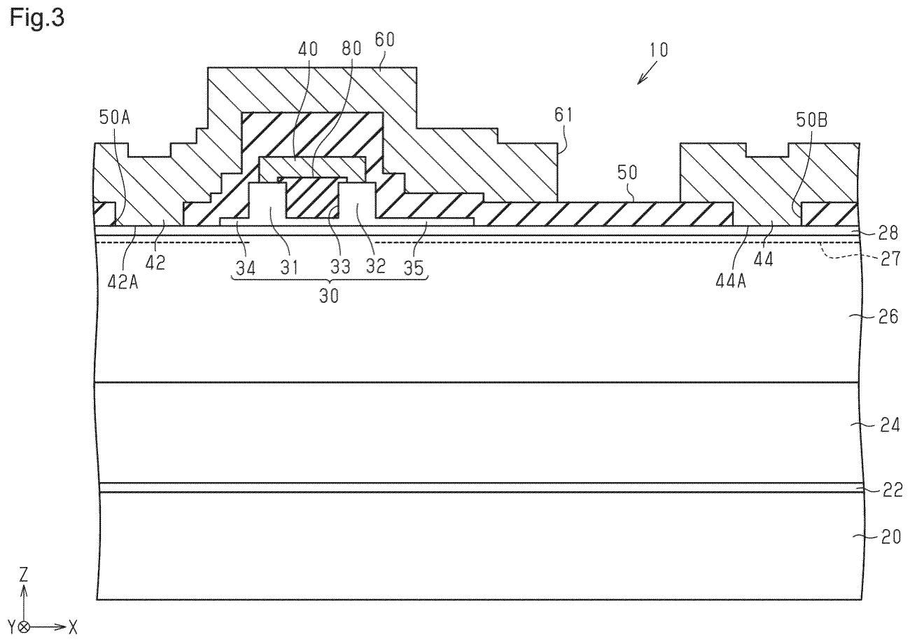

FIG. 2 is a schematic plan view illustrating part of the nitride semiconductor device 10 illustrated in FIG. 1. FIG. 3 is a schematic cross-sectional view of the nitride semiconductor device 10 taken along line F3-F3 in FIG. 2. The nitride semiconductor device 10 is a high-electron-mobility transistor (HEMT) that uses a nitride semiconductor.

As illustrated in FIG. 3, the nitride semiconductor device 10 includes a semiconductor substrate 20, a nucleation layer 22 formed on the semiconductor substrate 20, a buffer layer 24 formed on the nucleation layer 22, an electron transit layer 26 formed on the buffer layer 24, and an electron supply layer 28 formed on the electron transit layer 26.

The semiconductor substrate 20 may be composed of silicon (Si), silicon carbide (SiC), gallium nitride (GaN), sapphire, or other substrate materials. For example, the semiconductor substrate 20 may be a Si substrate. The semiconductor substrate 20 may have a thickness of, for example, 200 μm or greater and 1500 μm or less. The Z-axis direction corresponds to the thickness-wise direction of the semiconductor substrate 20.

The nucleation layer 22 is composed of a nitride semiconductor. For example, the nucleation layer 22 may be an aluminum nitride (AlN) layer having a thickness of 100 nm or greater and 500 nm or less. The nucleation layer 22 may be the lowermost layer of the buffer layer 24.

The buffer layer 24 may be composed of any material that reduces wafer warping and cracking that would be caused by the difference in the coefficient of thermal expansion between the semiconductor substrate 20 and the electron transit layer 26. The buffer layer 24 may include one or more nitride semiconductor layers. The buffer layer 24 includes, for example, at least one of an AlN layer, an aluminum gallium nitride (AlGaN) layer, and a graded AlGaN layer having different aluminum (Al) compositions. For example, the buffer layer 24 may include a single AlN layer, a single AlGaN layer, a layer having an AlGaN/GaN superlattice structure, a layer having an AlN/AlGaN superlattice structure, or a layer having an AlN/GaN superlattice structure.

The electron transit layer 26 is composed of a nitride semiconductor. The electron transit layer 26 may be, for example, a GaN layer. The electron transit layer 26 may have a thickness of, for example, 0.1 μm or greater and 2 μm or less. The electron transit layer 26 may include one or more nitride semiconductor layers. To reduce leakage current in the electron transit layer 26, part of the electron transit layer 26 may be doped with impurities so that regions other than the outermost part of the electron transit layer 26 is semi-insulating. In this case, the impurities are, for example, carbon (C). The concentration of the impurities may be, for example, greater than or equal to 1×10¹⁹ cm⁻³ at a peak concentration. GaN is one example of a first nitride semiconductor.

The electron supply layer 28 is composed of a nitride semiconductor having a larger bandgap than the electron transit layer 26. The electron supply layer 28 may be, for example, an AlGaN layer. The bandgap becomes larger as the Al composition increases. Thus, the electron supply layer 28, which is an AlGaN layer, has a larger band gap than the electron transit layer 26, which is a GaN layer. In one example, the electron supply layer 28 is composed of AlₓGa₁₋ₓN, where x is 0.1<x<0.4, and more preferably, 0.1<x<0.3. The electron supply layer 28 may have a thickness of, for example, 5 nm or greater and 20 nm or less. AlGaN is one example of a second nitride semiconductor.

The electron transit layer 26 and the electron supply layer 28 have bulk regions of different lattice constants. Thus, the nitride semiconductor of the electron transit layer 26 (e.g., GaN) and the nitride semiconductor of the electron supply layer 28 (e.g., AlGaN) form a lattice-mismatched heterojunction. The spontaneous polarization of the electron transit layer 26 and the electron supply layer 28 and the piezoelectric polarization resulting from the compression stress received by the heterojunction of the electron transit layer 26 cause the energy level of the conduction band of the electron transit layer 26 to be lower than the Fermi level in the proximity of the heterojunction interface between the electron transit layer 26 and the electron supply layer 28. Thus, a two-dimensional electron gas (2DEG) 27 forms in the electron transit layer 26 at a position proximate to (e.g., distanced by approximately a few nanometers from interface) the heterojunction interface of the electron transit layer 26 and the electron supply layer 28.

The nitride semiconductor device 10 further includes a gate layer 30, which is formed on part of the electron supply layer 28, and a gate electrode 40, which is formed on the gate layer 30.

The gate layer 30 is composed of a nitride semiconductor. For example, the gate layer 30 is composed of a nitride semiconductor having a smaller band gap than the electron supply layer 28 and containing acceptor impurities. In one example, the gate layer 30 is a GaN layer (p-type GaN layer) doped with acceptor impurities. Here, pGaN is one example of a third nitride semiconductor. The acceptor impurities may contain at least one of magnesium (Mg), zinc (Zn), and carbon (C). The maximum concentration of the acceptor impurity in the gate layer 30 is, for example, 7×10¹⁸ cm⁻³ or greater and 1×10²⁰ cm⁻³ or less.

The gate electrode 40 includes one or more metal layers. For example, the gate electrode 40 may be a titanium nitride (TiN) layer. Alternatively, the gate electrode 40 may be formed by a first metal layer that is composed of Ti and a second metal layer that is composed of TiN and arranged on the first metal layer. For example, the gate electrode 40 may be composed of a material forming a Schottky junction with the gate layer 30. One example of such a material is TiN. The gate electrode 40 may have a thickness of, for example, 50 nm or greater and 200 nm or less.

The nitride semiconductor device 10 further includes a passivation layer 50. The passivation layer 50 covers the electron supply layer 28, the gate layer 30, and the gate electrode 40. The passivation layer 50 may be composed of, for example, one or any combination of silicon dioxide (SiO₂), silicon nitride (SiN), silicon oxynitride (SiON), alumina (Al₂O₃), AlN, and aluminum oxynitride (AlON). The passivation layer 50 may have a thickness of, for example, greater than or equal to 50 nm and less than or equal to 200 nm, preferably, greater than or equal to 80 nm and less than or equal to 150 nm. The passivation layer 50 includes a source opening 50A and a drain opening 50B, each of which partially exposes the upper surface of the electron supply layer 28.

The nitride semiconductor device 10 further includes a source electrode 42, which is formed in the source opening 50A, and a drain electrode 44, which is formed in the drain opening 50B. The source electrode 42 includes a source contact 42A contacting the electron supply layer 28 through the source opening 50A. The drain electrode 44 includes a drain contact 44A contacting the electron supply layer 28 through the drain opening 50B.

The source electrode 42 and the drain electrode 44 each include one or more metal layers. For example, the source electrode 42 and the drain electrode 44 may be formed from one or any combination of Ti, TiN, Al, aluminum silicon copper (AlSiCu), and aluminum copper (AlCu).

The source opening 50A is filled with at least part of the source electrode 42, which is in ohmic contact through the source opening 50A with the 2DEG 27 located immediately below the electron supply layer 28. In the same manner, the drain opening 50B is filled with at least part of the drain electrode 44, which is in ohmic contact through the drain opening 50B with the 2DEG 27 located immediately below the electron supply layer 28. Although not illustrated in the drawings, the semiconductor substrate 20 is electrically connected to the source electrode 42, and voltage having the same potential as that at the source electrode 42 is applied to the semiconductor substrate 20.

In a structure in which the gate layer 30 is composed of a nitride semiconductor containing acceptor impurities, the 2DEG 27 is depleted in the region immediately below the gate layer 30 in a zero bias state in which voltage is not applied to the gate electrode 40 so that the conductive path (channel) is interrupted. Thus, the HEMT is of a normally-off type of which the threshold voltage is a positive value.

The nitride semiconductor device 10 further includes a field plate electrode 60 arranged on the passivation layer 50. The field plate electrode 60 is electrically connected to the source electrode 42. In the example of FIG. 3, the field plate electrode 60 is formed integrally with the source electrode 42, and part of the source electrode 42 acts as the field plate electrode 60. Accordingly, voltage having the same potential as that at the field plate electrode 60 is applied to the source electrode 42. The field plate electrode 60 is also referred to as a source field plate. The field plate electrode 60 covers the entire gate layer 30 in plan view.

The field plate electrode 60, which is separated from the drain electrode 44, has an end 61 located between the gate layer 30 and the drain electrode 44 in plan view. When drain voltage is applied to the drain electrode 44 in a zero bias state in which voltage is not applied to the gate electrode 40, the field plate electrode 60 acts to mitigate electric field concentration at the vicinity of the end of the gate electrode 40 and at the vicinity of the end of the gate layer 30.

### 2. Exemplary Structure of Gate Layer

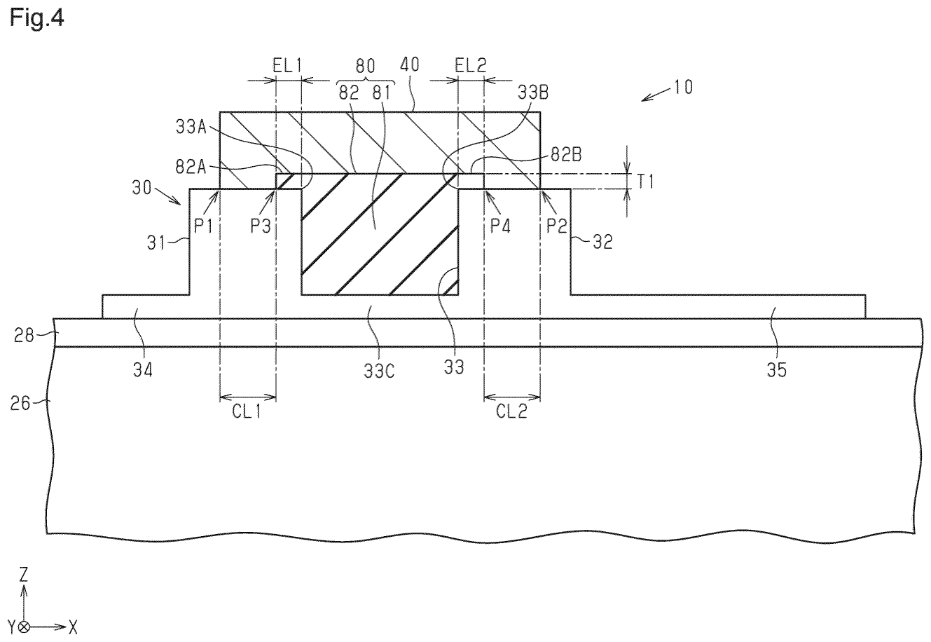

With reference to FIGS. 3 and 4, an exemplary structure of the gate layer 30 will now be described. FIG. 4 is a schematic, enlarged cross-sectional view illustrating part of the nitride semiconductor device 10 illustrated in FIG. 3.

The gate layer 30 is located between the source contact 42A and the drain contact 44A in the X-axis direction. The gate layer 30 is separated from both the source contact 42A and the drain contact 44A. Further, the gate layer 30 is located closer to the source contact 42A than the drain contact 44A.

The gate layer 30 includes a first gate portion 31, a second gate portion 32, and a recess 33 between the first gate portion 31 and the second gate portion 32. The gate electrode 40 is arranged over both the first gate portion 31 and the second gate portion 32. Thus, the first gate portion 31 and the second gate portion 32 are connected to each other by the gate electrode 40.

The first and second gate portions 31 and 32 each have, for example, a ridge-shaped cross section (rectangular cross section). The first gate portion 31 is not limited to any particular cross-sectional shape and may have, for example, a trapezoidal cross section or any other cross-sectional shape. The first and second gate portions 31 and 32 each have a thickness (distance from upper surface to lower surface of each of gate portions 31 and 32) that may be determined in accordance with various parameters such as the gate threshold voltage. For example, the first and second gate portions 31 and 32 may each have a thickness of greater than or equal to 80 nm and less than or equal to 150 nm.

The nitride semiconductor device 10 further includes an insulator 80 located in the recess 33. The insulator 80 is composed of one or any combination of SiO₂, SiN, SiON, Al₂O₃, AlN, and AlON. The gate electrode 40, which is arranged over both the first gate portion 31 and the second gate portion 32, covers the insulator 80.

As illustrated in FIG. 4, the insulator 80 includes a filler 81, which fills the recess 33, and an upper projection 82, which is formed integrally with the filler 81 and projects out of the recess 33. The upper projection 82 includes a first overlapping portion 82A, which covers part of an upper surface of the first gate portion 31, and a second overlapping portion 82B, which covers part of an upper surface of the second gate portion 32.

The first overlapping portion 82A extends in a-X direction (in FIG. 4, leftward in X-axis direction) over a first extension length EL1 from a first opening edge 33A of the recess 33 corresponding to an upper inner edge of the first gate portion 31 and covers the upper surface of the first gate portion 31. The second overlapping portion 82B extends in a +X direction (in FIG. 4, rightward in X-axis direction) over a second extension length EL2 from a second opening edge 33B of the recess 33 corresponding to an upper inner edge of the second gate portion 32 and covers the upper surface of the second gate portion 32. In the example of FIG. 4, the −X direction corresponds to a first direction, and the +X direction corresponds to a second direction.

The first overlapping portion 82A covers part, but not all, of the upper surface of the first gate portion 31. In one example, the first gate portion 31 may have a length in the X-axis direction of greater than and equal to 200 nm and less than or equal to 400 nm. Further, the first extension length EL1 of the first overlapping portion 82A may be, for example, greater than or equal to 10 nm and less than or equal to 200 nm. As long as the first overlapping portion 82A covers part of the upper surface of the first gate portion 31, the first extension length EL1 may be less than 10 nm. Further, to allow the normally-off HEMT to be smoothly switched on, it is preferred that the first extension length EL1 be relatively short. For example, in the embodiment in which the gate electrode 40 forms a Schottky junction with the gate layer 30, the first extension length EL1 may be less than or equal to 100 nm. The gate electrode 40 contacts the upper surface of the first gate portion 31 over a contact length CL1 in the X-axis direction. The contact length CL1 is set to a value that maintains the gate current supplying capacity taking into consideration the length of the first gate portion 31 in the X-axis direction, the first extension length EL1 of the first overlapping portion 82A, and the like. The first overlapping portion 82A has a thickness T1 set to a value that is less than the thickness of the gate electrode 40, for example, greater than or equal to 10 nm and less than or equal to 200 nm, more preferably, greater than or equal to 50 nm and less than or equal to 100 nm.

A side wall (left wall in FIG. 4) of the first gate portion 31 is connected in a stepped manner to a side wall (left wall in FIG. 4) of the gate electrode 40. Thus, the upper surface of the first gate portion 31 is exposed at the outer side (left side in FIG. 4) of the gate electrode 40, and a source-side space is defined above the upper surface.

In the same manner, the second overlapping portion 82B covers part, but not all, of the upper surface of the second gate portion 32. In one example, the second gate portion 32 may have a length in the X-axis direction of greater than and equal to 200 nm and less than or equal to 400 nm. The total length of the first gate portion 31 and the second gate portion 32 in the X-axis direction is, for example, greater than or equal to 400 nm and less than or equal to 800. The first and second gate portions 31 and 32 may have the same length or different lengths. The second extension length EL2 of the second overlapping portion 82B may be, for example, greater than or equal to 10 nm and less than or equal to 200 nm. As long as the second overlapping portion 82B covers part of the upper surface of the second gate portion 32, the second extension length EL2 may be less than 10 nm. Further, to allow the normally-off HEMT to be smoothly switched on, it is preferred that the second extension length EL2 be relatively short. For example, in the embodiment in which the gate electrode 40 forms a Schottky junction with the gate layer 30, the second extension length EL2 may be less than or equal to 100 nm. The gate electrode 40 contacts the upper surface of the second gate portion 32 over a contact length CL2 in the X-axis direction. The contact length CL2 is set to a value that maintains the gate current supplying capacity taking into consideration the length of the second gate portion 32 in the X-axis direction, the second extension length EL2 of the second overlapping portion 82B, and the like. The second overlapping portion 82B may have the thickness T1, which is the same as the first overlapping portion 82A.

A side wall (right wall in FIG. 4) of the second gate portion 32 is connected in a stepped manner to a side wall (right wall in FIG. 4) of the gate electrode 40. Thus, the upper surface of the second gate portion 32 is exposed at the outer side (right side in FIG. 4) of the gate electrode 40, and a drain-side space is defined above the upper surface.

The recess 33 includes a bottom portion 33C composed of a third nitride semiconductor (in first embodiment, pGaN). Thus, the insulator 80, which fills the recess 33, is arranged on the bottom portion 33C without contacting the electron supply layer 28. The bottom portion 33C is formed integrally with the first and second gate portions 31 and 32. In this manner, the first gate portion 31 and the second gate portion 32 are connected by the bottom portion 33C and thus not isolated from each other. The depth of the recess 33 is either the same as or different from the height of the side wall of each of the first and second gate portions 31 and 32.

The gate layer 30 further includes a source-side extension 34, which extends from the first gate portion 31 toward the source contact 42A (refer to FIG. 3), and a drain-side extension 35, which extends from the second gate portion 32 toward the drain contact 44A (refer to FIG. 3).

The source-side extension 34 and the drain-side extension 35 are composed of the third nitride semiconductor (in the first embodiment, pGaN). The source-side extension 34 has a thickness that is less than that of the first gate portion 31 and is formed integrally with the first gate portion 31. Further, the drain-side extension 35 has a thickness that is less than that of the second gate portion 32 and is formed integrally with the second gate portion 32. The source-side extension 34 and the drain-side extension 35 are both in contact with the electron supply layer 28.

The drain-side extension 35 has a greater length in the X-axis direction than the source-side extension 34. The length of the source-side extension 34 in the X-axis direction may be, for example, greater than or equal to 0.2 μm and less than or equal to 0.3 μm. The length of the drain-side extension 35 in the X-axis direction may be, for example, greater than or equal to 0.2 μm and less than or equal to 0.6 μm. The source-side extension 34 and the drain-side extension 35 enlarges the area over which the gate layer 30 contacts the electron supply layer 28.

### 3. Exemplary Planar Layout of Nitride Semiconductor Device

With reference to FIG. 2, an exemplary planar layout of the HEMT structure (nitride semiconductor device 10) will now be described. In FIG. 2, the passivation layer 50 is not illustrated to aid understanding. Further, the source opening 50A, the drain opening 50B, and the field plate electrode 60 are illustrated in broken lines.

As illustrated in FIG. 2, the nitride semiconductor device 10 includes gate wiring 72, source wiring 74, and drain wiring 76. The gate wiring 72, the source wiring 74, and the drain wiring 76 are formed on an interlayer insulative layer (not illustrated) covering the source electrode 42 and the drain electrode 44. For example, the gate wiring 72 is connected to the gate electrode 40 by gate connection conductors 73, which extend through the interlayer insulative layer to the gate electrode 40. The source wiring 74 is connected to the source electrode 42 by source connection conductors 75, which extend through the interlayer insulative layer. The drain wiring 76 is connected to the drain electrode 44 by drain connection conductors 77, which extend through the interlayer insulative layer.

The nitride semiconductor device 10 includes, in an element region, transistor elements that each have a HEMT structure. Although FIG. 2 illustrates transistor elements arranged next to one another in the X-axis direction, transistor elements are actually arranged next to one another in the X-axis direction and the Y-axis direction.

The drain electrode 44, which is provided for each transistor element, extends in the Y-axis direction in plan view. The source electrode 42, for example, surrounds each drain electrode 44 in plan view. As described with reference to FIG. 3, the source electrode 42 includes the field plate electrode 60. That is, the field plate electrode 60 is formed integrally with the source electrode 42 and extends toward the drain electrode 44 that is adjacent in plan view. In the example of FIG. 2, the source electrode 42 is formed continuously in the X-axis direction over the transistor elements that are adjacent to one another in the X-axis direction but may instead be separated into a number of portions in the X-axis direction.

The gate layer 30 and the gate electrode 40 are provided for each transistor element. Each gate layer 30 and each gate electrode 40 has a closed shape and surrounds one of the drain electrodes 44 in plan view.

The first gate portion 31, the second gate portion 32, the recess 33, and the insulator 80 are not illustrated in FIG. 2 to simplify illustration. In the gate layer 30 under the gate electrode 40, the recess 33 (refer to FIG. 3) may be, for example, elongated so as to extend in the Y-axis direction of FIG. 2. Further, in the gate layer 30 under the gate electrode 40, the insulator 80 (refer to FIG. 3) formed in the recess 33 may be, for example, an elongated insulation member extending in the Y-axis direction of FIG. 2.

### 4. Operation of Nitride Semiconductor Device

In an HEMT using a nitride semiconductor, when positive voltage is applied to a gate electrode, an electric field may locally concentrate at the part of a gate layer that is near a gate electrode end. Such local electric field concentration may result in crystal defect of the gate layer thereby causing the gate breakdown voltage to decrease. It is thus desirable that local electric field concentration be mitigated at the gate layer.

In the first embodiment, the gate layer 30 includes the first gate portion 31, the second gate portion 32, and the recess 33 located between the first gate portion 31 and the second gate portion 32. The gate electrode 40 is arranged over both the first gate portion 31 and the second gate portion 32. In this structure, the gate layer 30 is divided into the first and second gate portions 31 and 32. This scatters the locations where the electric field concentrates at the gate layer 30 and mitigates local electric field concentration.

Further, the gate electrode 40 extends continuously between the first and second gate portions 31 and 32. Thus, the gate electrode 40 lies on the insulator 80, which is arranged in the recess 33 between the first and second gate portions 31 and 32. This structure in which the insulator 80 and the gate electrode 40 are arranged above the recess 33 increases the gate breakdown voltage as compared to a structure in which the gate electrode 40 is separated into the first and second gate portions 31 and 32, for example, a structure in which electric gate portions are independently arranged on the first and second gate portions 31 and 32.

In a conventional gate structure in which the gate layer 30 is not separated into the first and second gate portions 31 and 32, for example, if the recess 33 and the insulator 80 were to be omitted from the gate layer 30 in the structure of FIG. 4, local electric field concentration will occur at upper surface locations P1 and P2 (refer to FIG. 4) where the gate layer 30 contacts the outer lower ends of the gate electrode 40. Further, in such a structure, the electric field intensity will become relatively large at the upper surface locations P1 and P2.

In contrast, with the structure in which the gate layer 30 is divided into the first and second gate portions 31 and 32, the locations where the electric field concentrates are also scattered to upper surface locations P3 and P4 (refer to FIG. 4) where the gate layer 30 contacts the inner lower end of the gate electrode 40. The upper surface location P3 corresponds to where the upper surface of the first gate portion 31 contacts the inner lower end of the gate electrode 40, and the upper surface location P4 corresponds to where the upper surface of the second gate portion 32 contacts the inner lower end of the gate electrode 40.

Further, in addition to the upper surface locations P3 and P4, the locations where electric field concentrates are also scattered to where an edge of the first gate portion 31 is located and where an edge of the second gate portion 32 is located, for example, the upper inner edge of the first gate portion 31 (i.e., the first opening edge 33A) and the upper inner edge of the second gate portion 32 (i.e., second opening edge 33B). In this manner, the locations where the electric field concentrates are scattered to the electric field upper surface locations P3 and P4 and to where the edges of the first and second gate portions 31 and 32 are located. This avoids a situation in which electric field is locally concentrated at only the upper surface locations P1 and P2 of the gate layer 30. Consequently, the maximum electric field intensity is reduced at the upper surface locations P1 and P2. This avoids crystal defects and crystal breakdowns. Thus, the gate breakdown voltage is increased.

Further, in the first embodiment, the nitride semiconductor device 10 includes the insulator 80, which is formed in the recess 33 of the gate layer 30. The insulator 80 includes the filler 81, with which the recess 33 is filled, and the upper projection 82, which is formed integrally with the filler 81 and which projects out of the recess 33. The upper projection 82 includes the first overlapping portion 82A, which covers part of the upper surface of the first gate portion 31, and the second overlapping portion 82B, which covers part of the upper surface of the second gate portion 32.

The first and second overlapping portions 82A and 82B are arranged between the gate electrode 40 and the first and second gate portions 31 and 32. This mitigates electric field concentration at where the edge of the first gate portion 31 is located (vicinity of upper inner end) and where the edge of the second gate portion 32 is located (vicinity of upper inner end). In this manner, part of the insulator 80 has the functionality of a field plate that mitigates electric field concentration.

In addition, the first and second overlapping portions 82A and 82B have the effect of reducing leakage current that flows inside the gate layer 30. In a structure in which the gate layer 30 is divided into the first and second gate portions 31 and 32, current may leak and flow through the two wall surfaces of the recess 33 (in FIG. 4, wall surface of recess 33 at first opening edge 33A and wall surface of recess 33 at second opening edge 33B).

In this respect, in the first embodiment, the first overlapping portion 82A extends onto the upper surface of the first gate portion 31 and covers the first opening edge 33A. This reduces current leakage from the first opening edge 33A through the wall surface of the recess 33. In the same manner, the second overlapping portion 82B extends onto the upper surface of the second gate portion 32 and covers the second opening edge 33B. This reduces current leakage from the second opening edge 33B through the wall surface of the recess 33. As a result, decreases in the gate breakdown voltage are limited when the gate layer 30 is divided into the first and second gate portions 31 and 32.

When compared with the conventional gate structure in which the gate layer 30 is not divided into the first and second gate portions 31 and 32, if the gate length is the same, the length of the gate layer 30 in the X-axis direction is relatively shorter by an amount corresponding to the length (width) of the recess 33 (insulator 80) in the structure in which the gate layer 30 is divided into the first and second gate portions 31 and 32. This substantially decreases the gate length and reduces the on resistance.

The nitride semiconductor device 10 of the first embodiment has the advantages described below.

(1-1) The gate layer 30 includes the first and second gate portions 31 and 32, and the gate electrode 40 is arranged over both the first and second gate portions 31 and 32. With this structure, the locations where the electric field concentrates at the gate layer 30 are scattered to multiple locations at each of the first and second gate portions 31 and 32. This mitigates electric field concentration at the gate layer 30 and increases the gate breakdown voltage. Further, the gate electrode 40 extends continuously between the first and second gate portions 31 and 32 on the insulator 80, which is arranged in the recess 33 between the first and second gate portions 31 and 32. This increases the gate breakdown voltage.

(1-2) When compared with the conventional gate structure, if the gate length is the same, the length of the gate layer 30 in the X-axis direction is relatively shorter by an amount corresponding to the length (width) of the recess 33 (insulator 80) in the structure in which the gate layer 30 is divided into the first and second gate portions 31 and 32. This reduces the on resistance.

(1-3) The insulator 80 is formed in the recess 33 of the gate layer 30. The insulator 80 includes the filler 81 and the upper projection 82. The upper projection 82 includes the first overlapping portion 82A, which covers part of the upper surface of the first gate portion 31, and the second overlapping portion 82B, which covers part of the upper surface of the second gate portion 32. With this structure, electric field concentration at the first and second gate portions 31 and 32 is mitigated at positions located immediately below the first and second overlapping portions 82A and 82B. Further, the first and second overlapping portions 82A and 82B reduce leakage current through the two wall surfaces of the recess 33.

(1-4) The first overlapping portion 82A extends over the first extension length EL1, and the second overlapping portion 82B extends over the second extension length EL2. In this case, preferably, the first extension length EL1 and the second extension length EL2 are each greater than or equal to 10 nm and less than or equal to 200 nm. With this structure, each of the extension lengths EL1 and EL2 are greater than or equal to 10 nm. This effectively mitigates electric field concentration at the gate layer 30 and effectively reduces current leakage. Further, the extension lengths EL1 and EL2 are less than or equal to 200 nm. This allows the HEMT to be smoothly turned on. For example, when the first extension length EL1 becomes greater than 200 nm, the area of the gate electrode 40 contacting the upper surface of the first gate portion 31 (contact length CL1) decreases and lowers the current supplying capacity of the first gate portion 31. As a result, the HEMT becomes difficult to turn on. Thus, it is desirable that the first extension length EL1 be 200 nm or less. The same applies to the second extension length EL2.

(1-5) The thickness of each of the first overlapping portion 82A and the second overlapping portion 82B is greater than or equal to 10 nm and less than or equal to 200 nm. With this structure, the thickness of 10 nm or greater effectively mitigates electric field concentration. The thickness of 200 nm or less effectively maintains the current supplying capability of the gate portions 31 and 32.

(1-6) The recess 33 includes the bottom portion 33C, and the insulator 80 is arranged on the bottom portion 33C without contacting the electron supply layer 28. With this structure, part of the gate layer 30, namely, the bottom portion 33C, is located immediately below the insulator 80. That is, the electron supply layer 28 is not exposed in the recess 33. This maintains the gate breakdown voltage in a preferred manner and is in contrast with a structure in which the insulator 80 contacts the electron supply layer 28.

(1-7) The gate layer 30 includes the source-side extension 34, which extends from the first gate portion 31 toward the source contact 42A, and the drain-side extension 35, which extends from the second gate portion 32 toward the drain contact 44A. With this structure, the locations where the electric field concentrates at the first and second gate portions 31 and 32 are scattered to the source-side extension 34 and the drain-side extension 35. This further increases the gate breakdown voltage.

### Second Embodiment

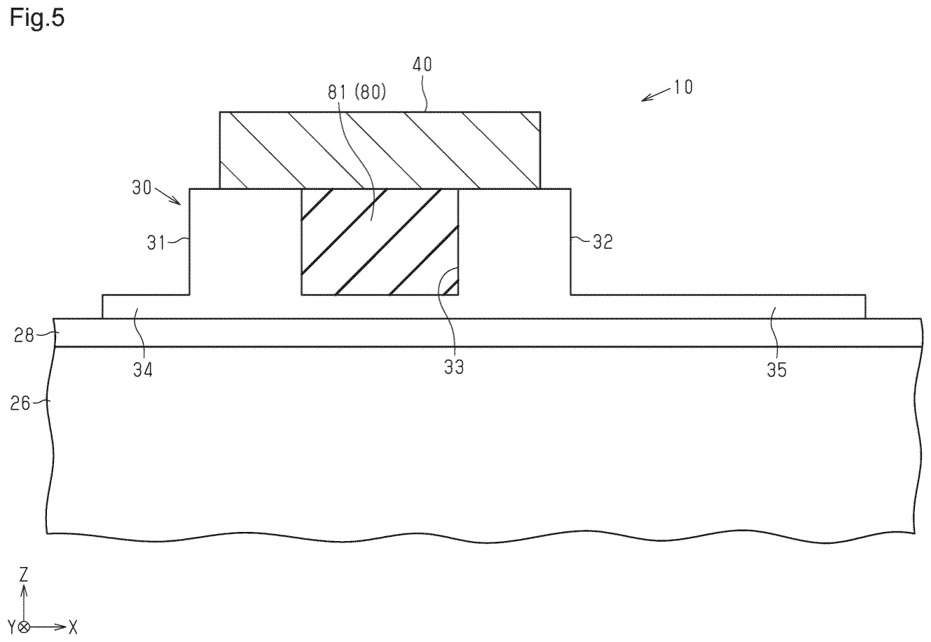

FIG. 5 is a schematic cross-sectional view of an exemplary nitride semiconductor device 10 in accordance with a second embodiment, and illustrates the cross-sectional gate structure of the second embodiment that corresponds to the cross-sectional gate structure of the first embodiment illustrated in FIGS. 3 and 4. In the second embodiment, the structure of the insulator 80 is partially changed from the first embodiment. Otherwise, the structure is the same as the first embodiment. Thus, similar elements will not be described in detail.

As illustrated in FIG. 5, in the second embodiment, the insulator 80 includes only the filler 81 and does not include the upper projection 82 (refer to FIGS. 3 and 4). That is, the upper projection 82 described in the first embodiment is omitted from the insulator 80. In this structure, the upper surface of the insulator 80 is flush with the upper surfaces of the first and second gate portions 31 and 32. Thus, the lower surface of the gate electrode 40 is flat and not stepped.

In addition to advantages (1-1), (1-2), (1-6), and (1-7) of the first embodiment, the nitride semiconductor device 10 in accordance with the second embodiment has the advantage described below.

(2-1) The insulator 80 of the second embodiment does not include the first and second overlapping portions 82A and 82B of the first embodiment. Thus, the first and second gate portions 31 and 32 have a higher current supplying capacity than the first embodiment.

### Third Embodiment

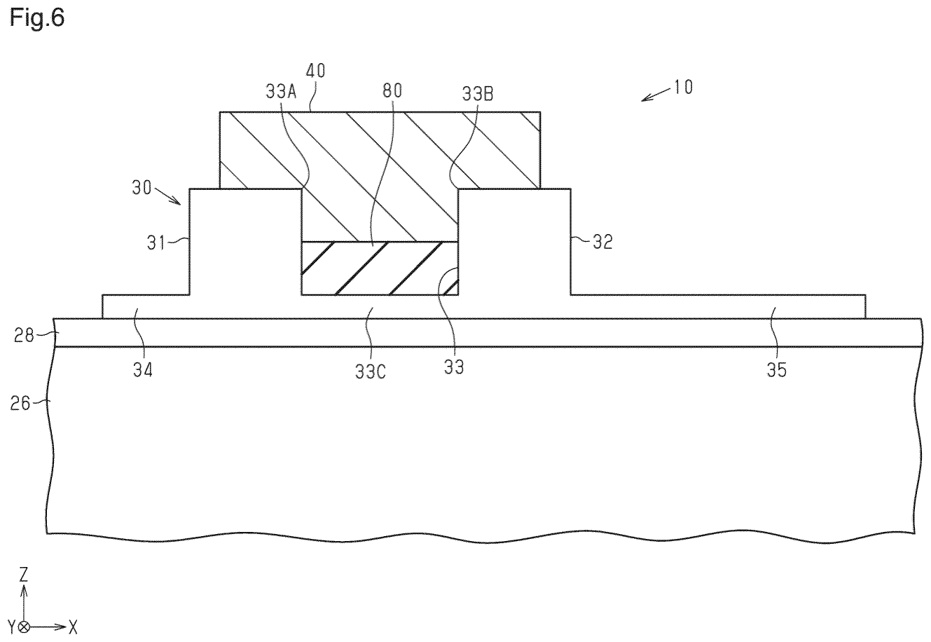

FIG. 6 is a schematic cross-sectional view of an exemplary nitride semiconductor device 10 in accordance with a third embodiment, and illustrates the cross-sectional gate structure of the second embodiment that corresponds to the cross-sectional gate structure of the first embodiment illustrated in FIGS. 3 and 4. In the third embodiment, the structure of the insulator 80 is partially changed from the first embodiment. Otherwise, the structure is the same as the first embodiment. Thus, similar elements will not be described in detail.

As illustrated in FIG. 6, in the third embodiment, the insulator 80 has a thickness that is less than that of each of the first and second gate portions 31 and 32. Thus, the insulator 80 is formed in part of the recess 33, but not throughout the entire recess 33. That is, the recess 33 is not entirely filled with the insulator 80. The gate electrode 40 is partially embedded in the recess 33. Thus, the insulator 80 and part of the gate electrode 40 is embedded in the recess 33.

The nitride semiconductor device 10 in accordance with the third embodiment has advantages that are similar to advantages (1-1), (1-2), (1-6), and (1-7) of the first embodiment.

### Fourth Embodiment

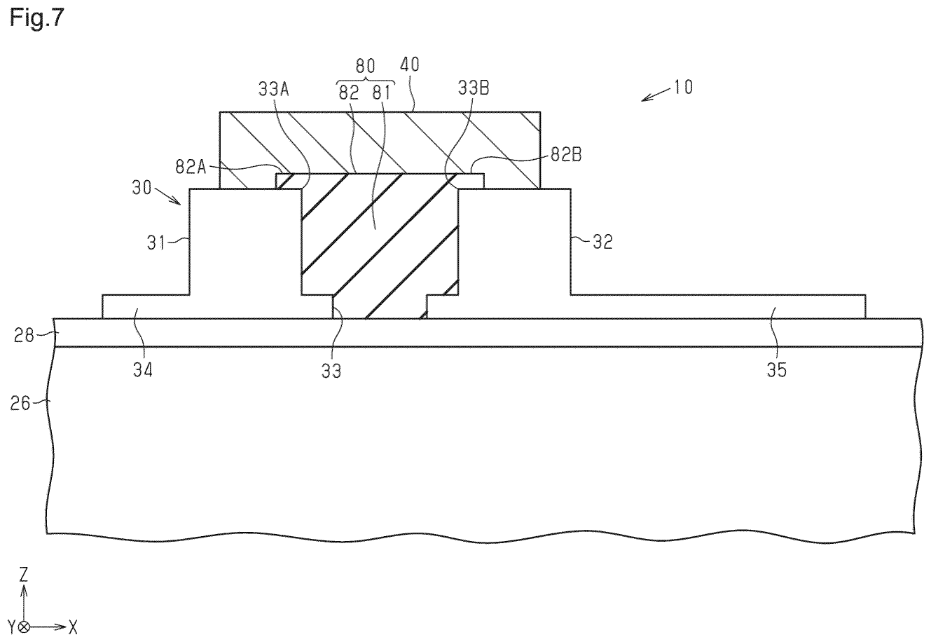

FIG. 7 is a schematic cross-sectional view of an exemplary nitride semiconductor device 10 in accordance with a fourth embodiment, and illustrates the cross-sectional gate structure of the fourth embodiment that corresponds to the cross-sectional gate structure of the first embodiment illustrated in FIGS. 3 and 4. In the fourth embodiment, the structure of the insulator 80 is partially changed from the first embodiment. Otherwise, the structure is the same as the first embodiment. Thus, similar elements will not be described in detail.

As illustrated in FIG. 7, in the fourth embodiment, the electron supply layer 28 is at least partially exposed in the recess 33, and the insulator 80 is in contact with the electron supply layer 28 in the recess 33. In FIG. 7, the first gate portion 31 and the second gate portion 32 are separated. However, the first gate portion 31 is connected to the second gate portion 32 in the gate layer 30 at a location where the recess 33 is not formed. Thus, the first gate portion 31 and the second gate portion 32 are not physically disconnected.

In addition to advantages (1-1) to (1-5) and (1-7) of the first embodiment, the nitride semiconductor device 10 in accordance with the fourth embodiment has the advantage described below.

(4-1) The electron supply layer 28 is at least partially exposed in the recess 33, and the gate layer 30 (e.g., pGaN layer) is omitted in the recess 33 at the location where the electron supply layer 28 is exposed. Thus, the 2DEG 27 (refer to FIG. 3) is generated in the region immediately below the recess 33. This structure is more advantageous for reducing the on resistance than the first embodiment.

### Modified Examples

The above embodiments may be modified as described below. The above-described embodiments and the modified examples described below may be combined as long as there is no technical contradiction.

The nitride semiconductor device 10 is not limited to a HEMT using GaN and may be a semiconductor device using a different nitride semiconductor.

The nitride semiconductor device 10 of the present disclosure is not limited to the numerical values or numerical value ranges described in the above-described embodiments.

The gate layer 30 is not limited to a structure including the source-side extension 34 and the drain-side extension 35. The source-side extension 34 and the drain-side extension 35 may be omitted from the gate layer 30.

The upper projection 82 of the insulator 80 does not have to include the first and second overlapping portions 82A and 82B. For example, in the structure of FIG. 4, the upper projection 82 may include only the part projecting upward from the filler 81, and the first and second overlapping portions 82A and 82B may be omitted.

The field plate electrode 60 does not have to be formed integrally with the source electrode 42. For example, voltage having the same potential as that at the source electrode 42 may be applied to the field plate electrode 60 that is physically separated from the source electrode 42.

The recess 33 may have, for example, a depth that is one-half the thickness of the first and second gate portions 31 and 32. In this manner, the depth of the recess 33 is not particularly limited.

The side wall (left wall in FIG. 4) of the first gate portion 31 does not have to be connected in a stepped manner to the side wall (left wall in FIG. 4) of the gate electrode 40, and may be flush with the side wall of the gate electrode 40. In the same manner, the side wall (right wall in FIG. 4) of the second gate portion 32 does not have to be connected in a stepped manner to the side wall (right wall in FIG. 4) of the gate electrode 40, and may be flush with the side wall of the gate electrode 40.

In this specification, the word “on” includes the meaning of “above” in addition to the meaning of “on” unless otherwise described in the context. Accordingly, for example, the expression of “first element mounted on second element” may mean that the first element is placed directly on the second element in one embodiment and mean that the first element is placed above the second element without contacting the second element in another embodiment. Thus, the word “on” will also allow for a structure in which another element is formed between the first element and the second element.

The Z-axis direction as referred to in this specification does not necessarily have to be the vertical direction and does not necessarily have to fully coincide with the vertical direction. Accordingly, in the structures of the present disclosure, “up” and “down” in the Z-axis direction as referred to in this specification are not limited to “up” and “down” in the vertical direction. For example, the X-axis direction may be the vertical direction. Alternatively, the Y-axis direction may be the vertical direction.

### CLAUSES

Technical concepts that can be understood from each of the above embodiments and modified examples will now be described. The reference characters used to denote elements of the embodiments are illustrated in parenthesis for the corresponding elements of the clauses described below. The reference characters are given as examples to aid understanding and not intended to limit elements to the elements denoted by the reference characters.

### [Clause 1]

A nitride semiconductor device (10), including:
an electron transit layer (26) composed of a first nitride semiconductor;
an electron supply layer (28) arranged on the electron transit layer (26) and composed of a second nitride semiconductor having a bandgap that is larger than that of the first nitride semiconductor;
a gate layer (30) arranged on part of the electron supply layer (28) and composed of a third nitride semiconductor;
a gate electrode (40) arranged on the gate layer (30); and
a source electrode (42) and a drain electrode (44) that are arranged on the electron supply layer (28), where
the gate layer (30) includes
   a first gate portion (31),
   a second gate portion (32), and
   a recess (33) between the first gate portion (31) and the second gate portion (32),
the gate electrode (40) is arranged over both the first gate portion (31) and the second gate portion (32), and
the nitride semiconductor device (10) further includes an insulator (80) located in the recess (33).

### [Clause 2]

The nitride semiconductor device (10) according to clause 1, where the insulator (80) includes
a filler (81) filling the recess (33) of the gate layer (30), and
an upper projection (82) formed integrally with the filler (81) and projecting out of the recess (33).

### [Clause 3]

The nitride semiconductor device (10) according to clause 2, where the upper projection (82) of the insulator (80) includes
a first overlapping portion (82A) covering part of an upper surface of the first gate portion (31), and
a second overlapping portion (82B) covering part of an upper surface of the second gate portion (32).

### [Clause 4]

The nitride semiconductor device (10) according to clause 3, where
the first overlapping portion (82A) extends in a first direction (−X) over a first extension length (EL1) from a first opening edge (33A) of the recess (33) corresponding to an upper inner edge of the first gate portion (31) and covers the upper surface of the first gate portion (31),
the second overlapping portion (82B) extends in a second direction (+X) that is opposite to the first direction (−X) over a second extension length (EL2) from a second opening edge (33B) of the recess (33) corresponding to an upper inner edge of the second gate portion (32) and covers the upper surface of the second gate portion (32), and
the first extension length (EL1) and the second extension length (EL2) are each greater than or equal to 10 nm and less than or equal to 200 nm.

### [Clause 5]

The nitride semiconductor device (10) according to clause 3 or 4, where the first overlapping portion (82A) and the second overlapping portion (82B) each have a thickness that is greater than or equal to 10 nm and less than or equal to 200 nm.

### [Clause 6]

The nitride semiconductor device (10) according to any one of clauses 1 to 5, where
the recess (33) includes a bottom portion (33C) composed of the third nitride semiconductor, and
the insulator (80) is arranged on the bottom portion (33C) without contacting the electron supply layer (28).

### [Clause 7]

The nitride semiconductor device (10) according to any one of clauses 1 to 5, where
the electron supply layer (28) is at least partially exposed in the recess (33); and
the insulator (80) is in contact with the electron supply layer (28) in the recess (33).

### [Clause 8]

The nitride semiconductor device (10) according to clause 1, where
the insulator (80) has a thickness that is less than that of each of the first gate portion (31) and the second gate portion (32), and
part of the gate electrode (40) is embedded in the recess (33).

### [Clause 9]

The nitride semiconductor device (10) according to any one of clauses 1 to 8, where
the source electrode (42) includes a source contact (42A) contacting the electron supply layer (28),
the drain electrode (44) includes a drain contact (44A) contacting the electron supply layer (28), and
the gate layer (30) includes
   a source-side extension (34) extending from the first gate portion (31) toward the source contact (42A), and
   a drain-side extension (35) extending from the second gate portion (32) toward the drain contact (44A).

### [Clause 10]

The nitride semiconductor device (10) according to any one of clauses 1 to 9, where the insulator (80) is composed of one or any combination of SiO₂, SiN, SiON, Al₂O₃, AlN, and AlON.

### [Clause 11]

The nitride semiconductor device (10) according to any one of clauses 1 to 10, where
the electron supply layer (28) is an AlGaN layer, and
the gate layer (30) is a GaN layer including acceptor impurities of at least one of Mg and Zn.

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in the disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer composed of a first nitride semiconductor;
an electron supply layer arranged on the electron transit layer and composed of a second nitride semiconductor having a bandgap that is larger than that of the first nitride semiconductor;
a gate layer arranged on part of the electron supply layer and composed of a third nitride semiconductor;
a gate electrode arranged on the gate layer; and
a source electrode and a drain electrode that are arranged on the electron supply layer, wherein
the gate layer includes
a first gate portion,
a second gate portion, and
a recess between the first gate portion and the second gate portion,
the gate electrode is arranged over both the first gate portion and the second gate portion, and
the nitride semiconductor device further includes an insulator located in the recess.

2. The nitride semiconductor device according to claim 1, wherein the insulator includes
a filler filling the recess of the gate layer, and
an upper projection formed integrally with the filler and projecting out of the recess.

3. The nitride semiconductor device according to claim 2, wherein the upper projection of the insulator includes
a first overlapping portion covering part of an upper surface of the first gate portion, and
a second overlapping portion covering part of an upper surface of the second gate portion.

4. The nitride semiconductor device according to claim 3, wherein
the first overlapping portion extends in a first direction over a first extension length from a first opening edge of the recess corresponding to an upper inner edge of the first gate portion and covers the upper surface of the first gate portion,
the second overlapping portion extends in a second direction that is opposite to the first direction over a second extension length from a second opening edge of the recess corresponding to an upper inner edge of the second gate portion and covers the upper surface of the second gate portion, and
the first extension length and the second extension length are each greater than or equal to 10 nm and less than or equal to 200 nm.

5. The nitride semiconductor device according to claim 3, wherein the first overlapping portion and the second overlapping portion each have a thickness that is greater than or equal to 10 nm and less than or equal to 200 nm.

6. The nitride semiconductor device according to claim 1, wherein
the recess includes a bottom portion composed of the third nitride semiconductor, and
the insulator is arranged on the bottom portion without contacting the electron supply layer.

7. The nitride semiconductor device according to claim 1, wherein
the electron supply layer is at least partially exposed in the recess, and
the insulator is in contact with the electron supply layer in the recess.

8. The nitride semiconductor device according to claim 1, wherein
the insulator has a thickness that is less than that of each of the first gate portion and the second gate portion, and
part of the gate electrode is embedded in the recess.

9. The nitride semiconductor device according to claim 1, wherein
the source electrode includes a source contact contacting the electron supply layer,
the drain electrode includes a drain contact contacting the electron supply layer, and
the gate layer includes
a source-side extension extending from the first gate portion toward the source contact, and
a drain-side extension extending from the second gate portion toward the drain contact.

10. The nitride semiconductor device according to claim 1, wherein the insulator is composed of one or any combination of SiO₂, SiN, SiON, Al₂O₃, AlN, and AlON.

11. The nitride semiconductor device according to claim 1, wherein
the electron supply layer is an AlGaN layer, and
the gate layer is a GaN layer including acceptor impurities of at least one of Mg and Zn.
